(19) United States
(12) Patent Application Publication
(10) Pub. No.: US 2026/0199894 A1
(43) Pub. Date: Jul. 16, 2026

(54) METHOD FOR MANUFACTURING A FLUIDIC DEVICE COMPRISING A SUBSTRATE BEARING AT LEAST ONE POROUS OR HOLLOW SOLID ELEMENT

(71) Applicants: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR)

(72) Inventors: Laurent MUGHERLI, Gif-Sur-Yvette Cedex (FR); Marc MALEVAL, Gif-Sur-Yvette Cedex (FR); Florent MALLOGGI, Gif-Sur-Yvette Cedex (FR)

(21) Appl. No.: 19/136,266

(22) PCT Filed: Dec. 8, 2023
(86) PCT No.: PCT/EP2023/084981

§ 371 Date: Jun. 5, 2025

(30) Foreign Application Priority Data
Dec. 9, 2022 (FR) FR2213105

(51) Int. Cl. B01L 3/00; B81C 1/00

(52) U.S. Cl. CPC B01L 3/502707; B81C 1/00119; B01L 2300/0883; B81B 2201/05

(57) ABSTRACT

A method for manufacturing a device (10) for the flow of a fluid along at least one fluid flow path passing through a hollow or porous solid element (30) and at least part of a fluidic circuit (50) which are fluidically connected to one another, the method including the following steps: e) printing the path (62) of the fluidic circuit (50) on a support with an ink and disposing the solid element (30) on the support, the ink being contiguous with the solid element (30) on the fluid flow path, f) covering the solidified ink and the solid element (30) with a crosslinkable polymer (25), the polymer (25) being immiscible with the solidified ink; g) crosslinking the polymer (25) to solidify it; then h) extracting the solidified ink to form the fluid flow path.

The present invention relates to a method for manufacturing a device for the flow of a fluid on at least one fluid flow path passing through a porous or hollow solid element and at least part of a fluidic circuit.

### TECHNICAL FIELD

The integration of hollow or porous elements in fluidic devices, microfluidic in particular, is a challenge, owing to the need to position the hollow or porous element precisely in the device in order to ensure (i) connection with the fluidic circuit, (ii) flow of fluid in the hollow or porous element, and (iii) maintenance of the properties of the hollow or porous element, in particular the integrity of the pores or hollows and/or the permeability of the hollow or porous element, but also its separative or catalytic function, for example.

Most methods for manufacturing a fluidic device allow the generation of open zones, channels in particular, in a solid material by means of at least one step involving the use of a liquid precursor, which solidifies subsequently to form an impervious wall between the open zones and the solid material. The liquid precursor is solidified in particular by polymerization, in the manufacture, for example, of PDMS chips or following cooling after heating to above the glass transition of the polymer, as with chips made from molded thermoplastic.

For these methods, a first approach, referred to as an ex situ technique, involves positioning a hollow or porous element before manufacturing the chip. However, by this technique, the liquid precursor will naturally enter the open spaces and will no longer be able to be withdrawn when solidified, which will prevent flow of the liquid in the hollow or porous element after solidification. This problem is particularly serious for small-sized elements compatible with miniaturized systems, but it may also be encountered for larger-sized hollow or porous elements that may be intended for encapsulation with a liquid which solidifies to give greater imperviousness than that achieved by use and application of a heat-shrinking sheath—for example, for shapes which are complex or exhibit sharp projecting edges. This penetration of the liquid into the open spaces is not only an interference for the porous or hollow materials, but also limits the connection of these elements to the fluid flow. In particular, this makes it necessary to have a fluidic circuit with a cross section perfectly adapted to the porous element, the latter being then fixed, in order to ensure that the liquid flowing in the circuit inevitably traverses the circuit. It is also necessary that the hollow or porous element does not become deteriorated when it is incorporated, and more particularly that it retains its integrity, its porosity and/or its hollow or porous volume.

The customary solutions for integrating a porous or hollow solid element into a fluid channel employ the forced insertion of the solid element into a channel, or else employ sheaths which conform to the shape of the material, heat-shrinking sheaths in particular, as is described in the article by Namera et al., Trends in Analytical Chemistry, vol. 45, 2013; Nakanishi, Wiley, Synthesis Concepts and Preparation of Silica Monoliths, 2011-10.1002/9783527633241.ch2. These techniques are limited by the mechanical stresses to which the element is subject, more particularly when said element is small in size. For example, cylindrical monoliths with a hierarchical porosity and a diameter of more than 3 mm can be placed in heat-shrinking sheaths, but for diameters of less than 3 mm, problems are observed, such as the deterioration of the material following shrinking of the sheath.

Han et al., Microsystems & Nanoengineering 2019, 5:30 describe porous elements which are encapsulated in sheaths which are then included in acrylic polymethyl methacrylate (PMMA), for example, but for very simple architectures involving a single channel. The solution of integration into solid sheaths is extremely limiting, technically, for producing fluidic devices, more particularly if one or more functions have to be integrated into a complex fluidic architecture. This is even more true in the case of functions which themselves require complex architectures, such as integration of moving elements, or of optical constraints, for example.

Patent applications U.S. Pat. No. 7,651,762 B2 and WO2004/039495 disclose the manufacture of sheaths via liquids which solidify. This is an alternative which enables perfect conformity to the shape of the hollow or porous elements. This type of technique is used in particular for manufacturing certain chromatography columns with diameters of greater than 1 mm. However, the lower the diameter of the material, the more difficult it becomes to implement the techniques based on liquids which solidify, owing in particular to the penetration of the liquid into part of the open spaces or pores. This is a major disadvantage for miniaturization, and it becomes particularly detrimental for elements of low diameters or thickness, typically cylinders with diameters of less than or equal to 2 mm. Moreover, such materials encapsulate the solid element completely, so preventing it from being integrated into a fluidic circuit.

A second technique, referred to as an in situ technique, involves integrating in the fluidic device, after manufacture and solidification thereof, the various elements possessing open spaces, pores in particular. To do this, the hollow or porous elements are then manufactured directly in the device. Patent application EP3017866B1 and the article by Wu et al., Anal. Chem. 2006, 78 (16), 5704-5710 describe such manufacture in situ. Nevertheless, apart from the fact that the size of the hollow or porous elements generated may be difficult to control, the porosity and structural properties of the hollow or porous element may be difficult to reproduce, and there may be a loss of imperviousness between the hollow or porous element and the fluidic device. Such problems of maintenance of properties, of imperviousness and, more generally, of reproducibility are also encountered in the literature relating to the in situ synthesis of porous materials, and this is particularly the case with monoliths obtained by a sol-gel process, for which integration into a single glass capillary is already difficult, as demonstrated by the article by Ishizuka et al., Journal of Chromatography A (2002), 960 (1-2), 85-96.

For the manufacture of fluidic devices, international patent application WO2019/077144 discloses the use of a sacrificial ink to draw the fluidic circuit on a support, before covering the ink with a crosslinkable polymer and, after solidification of the polymer, removing the ink to form the fluidic circuit within the structure of crosslinked polymer.

In light of the difficulties presented above, it is understood that producing fluidic devices which integrate hollow or porous elements with complex designs, combining two or more functions on a reduced space, for example, is difficult.

There is a need, therefore, for a method for manufacturing a fluidic device that enables a porous or hollow solid element to be integrated in a way which is simple, universal or at least compatible with the majority of methods for manufacturing fluidic devices, without making them more complex, and which is reproducible from the standpoint of the flow of fluids and functionalities, and is robust. This is needed in particular in order to be able to produce columns, extraction supports, catalysts and microsystems, without the need to deploy expertise and research again in order to adapt the necessary experimental parameters again, owing to a change in format and/or in size of the hollow or porous element.

### SUMMARY OF THE INVENTION

The invention meets this need by means of a method for manufacturing a device for the flow of a fluid on at least one fluid flow path passing through a porous or hollow solid element and at least a part of a fluidic circuit, the solid element and the part of the fluidic circuit being fluidically connected to one another, the method comprising the following steps:
a) printing a support with the course of the fluidic circuit with an ink and disposing the solid element on the support, the ink being contiguous with the solid element on the fluid flow path;
b) covering the solidified ink and the solid element with a crosslinkable polymer, the polymer being immiscible with the solidified ink;
c) crosslinking the polymer to solidify it; then
d) extracting the solidified ink to form the fluid flow path.

Fluidically connected to one another means that a fluid is able to pass from one to the other by a fluid flow zone which extends between the two. The fluidic connection between the solid element and the fluidic circuit is preferably accomplished directly by the unblocking of at least one pore, preferably two or more pores, or of the or of at least one hollow of the solid element on a portion of the fluidic circuit.

Printing a support with the course of the fluidic circuit with an ink means that the ink is placed on the support in order to reproduce the course of the fluidic circuit on the support, with the built-up zones formed by the ink representing the course of the recessed zones of the fluidic circuit.

Flow of a fluid on a fluid flow path passing through a porous or hollow solid element and at least a part of a fluidic circuit means that after the extraction of the ink in step d), there is a continuous path passing through the solid element and through at least a part of the fluidic circuit, via which a fluid is able to flow. This implies that the solid element, after manufacture of the device, retains within it a traversing path via which a fluid is able to flow, and that the connection between the solid element and the fluidic circuit allows fluid to flow from one to the other, the ink and the solid element being joined on a surface of the solid element from which pores open out or at least one hollow of the solid element opens out.

Immiscible means that the solidified ink does not mix with the polymer.

A method of this kind allows a hollow or porous solid element to be easily integrated in a fluidic circuit while allowing a fluid to flow within it in the fluidic circuit. The ink allows one or more microcavities and/or one or more microchannels, forming the fluidic circuit, to form within the polymer. As it comes into contact with the solid element on the fluid flow path, the solid element is protected at its junction with the ink from contact with the polymer in this zone, thereby preventing the polymer from penetrating the hollow or the pores at this junction during step b) of covering with the polymer. Therefore, after the ink extraction step, at least one of the microcavities or one of the microchannels is directly linked fluidically to the hollow or free pores of the fluid flow surface of the solid element.

Extraction of the ink in step d) after solidification of the polymer allows recessed zones of the fluidic circuit to form, which partially define the fluid path in the solidified polymer. The junction between the ink and the porous element on the fluid flow path in step a) makes it possible at this junction to leave a zone for passage of the fluid from the solid element to the circuit formed by extraction of the ink; the flow of the fluid is not blocked by the polymer at this junction, owing to the presence of the ink.

The solid element may be disposed on the support in a predetermined zone of the support, the predetermined zone being determined such that the solid element is on the fluid flow path and that the solid element is contiguous with at least a part of the fluidic circuit.

### Method

### Maintenance of a Fluid Flow Path

The method preferably comprises a step of protecting at least a part of the pores or of the hollow or hollows of the solid element along the fluid flow path. The protection step may comprise the filling of at least a part of the solid element, in particular the core of the solid element, more preferably all of the solid element, prior to the covering step b), with a protective agent which prevents penetration of the polymer into the solid element in the covering step b), and a step of extracting the protective agent after the polymer crosslinking step c) to enable fluid flow in the solid element. The protective agent is preferably liquid when it is introduced into the solid element, and solidifies before the covering of the solid element with the polymer. The solid element may be cooled to a temperature lower than the solidification temperature of the protective agent.

The solidified protective agent is preferably immiscible with the polymer. The solidified protective agent may be extracted before, at the same time as or after the extraction of the ink. The protective agent is preferably extracted simultaneously with the extraction of the ink, by the same extraction technique.

The filling of at least a part of the solid element, in particular the core of the solid element, more preferably all of the solid element, with the protective agent may be accomplished before the step a) of printing the ink and disposing the solid element.

The protective agent is preferably miscible with the ink for printing the fluidic circuit. This facilitates the joining of the solid element with the ink in step b).

The protective agent may be identical with the ink for printing the course of the fluidic circuit. In that case, the filling of at least a part of the solid element, in particular the core of the solid element, more preferably all of the solid element, with the protective agent may precede the printing of the ink, or, as a variant, step a) may comprise disposing the solid element on the support and then printing the ink on the support such that the ink fills at least a part of the solid element, in particular the core of the solid element, more preferably all of the solid element.

As a variant, in the case of a porous solid element, the polymer is crosslinked before the polymer has been able to fill the pores of at least one flow cross section of the fluid flow path of the solid element.

The method may be configured such that the polymer, outside the surface zone of the solid element in contact with the ink, penetrates the pores of the solid element between the covering step b) and the crosslinking step c) over a skin thickness of the solid element of less than or equal to 40%, more preferably less than or equal to 30%, more preferably still less than or equal to 20%, preferentially less than or equal to 10%, of the smallest dimension of the solid element in each flow cross section of the fluid flow path in the solid element. Flow cross section of the fluid flow path in the solid element means a section across the fluid flow path in the solid element. This makes it possible to leave a zone within the solid element, at each flow cross section within the solid element, for flow of fluid along the fluid path.

### Step a)

The support is preferably cooled to a temperature lower than the solidification temperature of the ink.

The ink may be printed before the hollow or porous element is disposed on the support, or conversely after the hollow or porous element is disposed on the support.

The course may be continuous or discontinuous. It may comprise a plurality of continuous portions of printing, the continuous portions being discontinuous with one another, connected to one another in particular by the solid element and/or complementary solid elements.

The method may comprise a prior treatment of the support to enhance its force of adhesion with the ink to be deposited and/or the polymer intended for forming the shell.

The ink may be printed by inkjet printing, by means of a printing nozzle and a liquid ink having a viscosity of less than or equal to 30 mPa·s⁻¹. The distance between said printing nozzle on the one hand and the support on the other hand may be between 0.5 mm and 20 mm. The size of a drop of ink ejected by said printing nozzle may be between 10 μm and 100 μm. The frequency with which drops of ink are ejected from said nozzle may be between 50 Hz and 5 kHz. The support on the one hand and said printing nozzle on the other hand may be adapted to permit relative displacement of the one relative to the other with a controlled relative displacement velocity of between 1 mm/s and 100 mm/s.

As a variant, the ink is printed by means of a syringe containing the ink. The distance between one end of the syringe via which the ink is dispensed, on the one hand, and the support on the other hand may be between 0.1 mm and 1 mm. The flow rate of ink dispensed by the end of said syringe may be between 0.01 nl/s and 10 nl/s. The support on the one hand and said syringe end on the other hand may be adapted to permit relative displacement of the one relative to the other with a controlled relative displacement velocity of between 0.1 mm/s and 10 mm/s.

Printing may be accomplished by printing on a preferably flat printing surface of the support. As a variant, the printing surface may be curved, in particular concave or convex.

The method may comprise local printing of a plurality of successive layers of ink one atop another after solidification of the ink between each layer, to give a predetermined thickness of the ink printed on the support and hence to give a predetermined local depth of a structure of the fluidic circuit. This provides access to a great many device architectures in connection with a wide variety of solid elements, and so makes the method versatile.

The step of printing the course and disposing the solid element may comprise a first printing of ink to form the course of the fluidic circuit, the disposing of the solid element on the support, then a second printing of ink, in particular at the junction between the solid element and the first printing of ink, to form the junction between the solid element and the ink of the first printing. Via this technique it is possible to have a junction between the solid element and the ink that prevents the polymer penetrating between them. Moreover, it enables an effective junction in spite of the imperfections of manufacturing, and so enhances the reproducibility of the method. Lastly, it allows the porous element to be locked in position, in particular during the addition of the polymer, and this further enhances the effective formation of the fluid flow path.

The thickness of the ink at the junction with the solid element is preferably substantially equal to the thickness of the solid element at the same junction. The cross section of the ink placed at the junction is preferably substantially equal to the cross section of the solid element at the junction. As a variant, the cross sections are different.

As a variant, the method may comprise printing at least two respectively continuous portions separate from one another to form the course of the fluidic circuit, and disposing the solid element at least partially between the two continuous structures. This makes it possible to form a junction by a solid element between the two continuous portions which, after extraction of the ink, will form conduits. The fluid flow path will then necessarily proceed via the pores or the hollow in the solid element between the two portions.

The solid element may be disposed straddling the two continuous portions. In this embodiment, each end of the solid element may extend over one of the two continuous portions. The two continuous portions may comprise notches for receiving the ends of the solid element. This makes it possible in particular to raise the solid element relative to the support, with the two continuous portions forming raising blocks during manufacture. Accordingly, during covering with the polymer, a part of the polymer will spread under the solid element between the two continuous portions in such a way that the solid element will be encapsulated in the polymer and not on the surface of the latter. As a result, in particular, the solid element can be held during extraction of the ink to form the fluid flow path, as we will see later on. This allows the holding of the solid element on the portions and the fluid junction at the ends of the solid element, enhancing contact between the ink and the solid element.

Furthermore, it is preferable in this case to provide for printing twice, as explained above, once before the disposing of the solid element and once after, to enhance the hold of the solid element when the polymer is inserted and also the junction between the solid element and the ink.

The method may comprise a step of solidifying the ink and/or the protective agent before covering with the polymer in step b). This step may be spontaneous in light of the nature of the ink and/or of the protective agent, in particular by awaiting a solidification time, in particular a time for evaporation of a solvent, or it may be controlled, in particular by heating.

Between steps a) and b), the method may comprise an anneal at a temperature lower than the extraction temperature of the ink and, where appropriate, of the protective agent. Such annealing allows the roughness of the surface of the course deposited to be reduced. Indeed, when the ink has solidified, and in spite of the care taken with the deposition conditions, it may be noted that the surface of the ink in solid form exhibits significant roughness. This roughness, consequently, may transfer to the polymer walls of the fluidic circuit. The roughness may have a not insignificant effect on the flow conditions in the device and, consequently, may give rise to head losses and/or undesirable heat exchange, or may modify the analytical conditions.

The method may comprise the disposing of a plurality of hollow and/or porous solid elements in step a), the solid elements each being contiguous with the printed ink along the fluid flow path. The solid elements may be fluidically connected to one another in series or in parallel by one or more continuous portions of the fluidic circuit along the fluid flow path. The solid elements may have substantially the same dimensions, structure and/or porosity or, as a variant, may be different in their dimensions, structure and/or porosity. The continuous portions of the fluidic circuit may form junctions between two or more solid elements, which in particular are different in nature, more specifically between a recessed solid element forming a channel, and a porous solid element.

The method may comprise the addition of one or more solid complementary elements in step a). The one or more complementary elements may be selected from:
interconnect elements enabling flow of the fluid in the fluidic circuit, in particular for connecting the fluidic circuit to the fluid entry or exit or for connecting the device to another, identical or different, device, and/or
elements for arrangement of the solid element on the support-in particular, blocks each disposed at least partially under at least one part of the solid element, in particular under each of its ends.

### Covering

The step of covering the solid element and the solidified ink with the polymer may take place by pouring the polymer onto the support, the solid element and the printed solidified ink.

The polymer introduced in step b) may comprise: polydimethylsiloxane (PDMS), polyimides, agarose gels or a glue such as acrylic or mixtures thereof.

The polymer may comprise a crosslinking additive. The additive may be a crosslinking agent, in particular methylhydrosiloxane, a photoinitiator, in particular 1-hydroxycyclohexyl phenyl ketone or benzophenone or quinone, or a solvent, in particular formaldehyde.

Where the additive is a crosslinking agent, and depending on the nature of this crosslinker and/or the polymer, crosslinking may take place at ambient temperature, optionally aided by gentle heating to accelerate crosslinking. Also when the additive is a crosslinking agent, and if the nature of the crosslinker and/or of the polymer does not allow crosslinking at ambient temperature, crosslinking may take place by heating, in particular at a temperature lower than the extraction temperature of the ink at equivalent pressure and, where appropriate, of the protective liquid.

Where the additive is a photoinitiator, crosslinking may take place by subjecting the polymer to ultraviolet radiation. A photoinitiator may be contemplated in particular with certain glues, which then become crosslinkable by ultraviolet.

Lastly, where the additive is a solvent, crosslinking comprises evaporation of the solvent, which takes place generally at ambient temperature. Once the solvent has evaporated, the polymer crosslinks.

Crosslinking of the polymer is preferably controlled such that the crosslinking time is less than the time for filling of the porous solid element by the polymer. The crosslinking time may be controlled by controlling the temperature and/or pressure at which the polymer is crosslinked.

### Extraction

Extraction of the ink and, where appropriate, of the protective agent may be accomplished by any technique that retains the integrity of the solid element and the crosslinked polymer. Preferably, extraction of the ink and, where appropriate, of the protective agent is accomplished by vaporizing the ink and, where appropriate, the protective agent and then evacuating the vapor.

Extraction of the ink and/or the protective agent may be accomplished, depending in particular on the nature of the ink and, where appropriate, the protective agent, by sublimation or, depending on the nature of the ink and/or the protective agent, liquefaction and then evaporation of the ink and, where appropriate, the solidified protective agent. Other extraction solutions are possible if they allow the ink to be extracted to form the fluid flow path. Depending on the nature of the ink and the crosslinkable polymer, for example, consideration may be given to thermal decomposition by heat treatment at an ink decomposition temperature lower than the melting temperature of the crosslinkable polymer, or dilution by circulation of an ink dilution product with or without prior liquefaction of the ink, or aspiration/overpressure with prior liquefaction of the ink. Preferably, the extraction temperature of the ink and, where appropriate, the solidified protective agent is lower than the melting temperature of the polymer at equivalent pressure.

Therefore, to sublimate the ink and, where appropriate, the protective agent, the extraction step may take place by heating and by applying a pressure differential between the inside of the assembly formed at the end of step c) and the outside. This makes it possible to position the system, within the phase diagram of the ink and, where appropriate, the protective agent, at a pressure/temperature combination that directly allows passage from the solid state to the vapor state. When this can be envisaged, it is particularly advantageous, since it limits the level of heating of the assembly formed in step c), and hence the energy expended, in order to vaporize the ink and, where appropriate, the protective agent and so to remove it or them so as to form the fluid flow path.

As a variant, the extraction step d) is carried out by heating so as to ensure the liquefaction then vaporization of the ink and, where appropriate, the protective agent.

The method may comprise washing the device after extraction of the ink and/or the protective agent, by circulating a washing liquid in the device along the fluid flow path. The method may comprise a step of drying the device after washing.

Before or after the covering with the polymer and before or after the extraction, the method may comprise the addition of additional structures on or in the polymer, in particular a piercing structure in the polymer for connecting the fluidic circuit in the polymer to the outside.

As a variant, when the ink is deposited at least partially in contact with the support, the extraction of the ink may comprise
the separation of the initial support of the assembly formed at least from the crosslinked polymer, the ink and the solid element forming a single block, then
the extraction of the ink from the assembly, in particular by dissolution in alcohol and/or vaporization or sublimation of the ink as described above, and
the installation of the assembly from which the ink has been extracted to form the fluidic circuit on a support identical to or different from the initial support. Fastening on said support may be accomplished by adhesion of the polymer on the support, with or without adhesive, or by any other known technique enabling impervious adhesion on the support.

This variant is applicable more particularly when the solid element is at least partially encapsulated in the polymer, the solid element being raised relative to the support. The reason, with the solid element being held in the polymer, is that it is then easier to detach and reaffix the assembly of the support, since the solid element is not in contact with the latter. In the case of a solid element flush with the support, this variant is also applicable but is not preferred.

### Support

The support may comprise a substrate made of a hydrophobic material selected for example from the following: polyimides (PI), silicones, including poly dimethylsiloxane (PDMS), polypropylene (PP), polytetrafluoroethylene (PTFE) and cyclic olefin copolymer (COC), or a hydrophilic material selected from silicon, glass, cellulose and glass fibers.

The substrate may be rigid. The substrate may be multilayered.

The printing surface may be a surface of the substrate. The printing surface may be flat. As a variant, the printing surface is not flat, and in particular is curved, more particularly concave or convex, or comprises surface reliefs.

The method may comprise the withdrawal of at least a part of the support, in particular the substrate.

As a variant, the support comprises a substrate as described above and one or more support elements placed on the substrate. The support elements, where appropriate, may have the same thickness, taken across the plane of extension of the substrate. The printing surface may comprise an outer surface of the or of each support element. The outer surface or surfaces may be flat. The outer surfaces of the printing surface may be coplanar. The method may comprise a step of forming the support by adding the one or more support elements on the substrate.

The support may comprise at least two support elements, in particular made of a crosslinked polymer identical with that of step b), on the substrate, which are spaced apart by a nonzero distance, the device being configured such that the solid element is disposed in step a) straddling the two support elements and such that the ink is printed on one or the two support elements. This case is particularly useful when the substrate is withdrawn after step c) or d) as is described below, since it reinforces the rigidity of the device by encapsulation of the solid element and the fluidic circuit in the polymer.

The contact surface between the solid element and the support may be disposed at the same level as the surface for printing of the ink.

As a variant, the support comprises a cavity for receiving the solid element on the surface configured for receiving the solid element, the solid element being disposed in the cavity in step a). A cavity of this kind allows the porous element to be positioned easily and precisely on the support. It also allows the porous element to be held on the support during the step of printing the ink and the step of covering with the polymer. The cavity for receiving the solid element preferably has a depth less than or equal to the size of the solid element taken perpendicularly to the support, in particular less than or equal to the thickness of the solid element, in order to enable the junction between the ink and the solid element to form the fluidic circuit. The depth of the cavity for receiving the solid element may be less than or equal to 80%, more preferably 50%, of the size of the solid element taken perpendicularly to the support. The cavity for receiving the solid element may be formed by a recess or a trench on the substrate or on a crosslinked polymer layer of the support, adjusted or not adjusted to the shape of the solid element, in which the solid element is disposed in step a). As a variant, the cavity for receiving the solid element is delimited by a plurality of surface elements, made in particular of crosslinked polymer identical with that of step b), which are arranged on the substrate to form the cavity for receiving the solid element. In this case, the solid element is disposed on the substrate in the cavity and is bordered in contact on at least one of its sides, more preferably at least at two of its sides, more preferably still at least at its two longitudinal ends, by the surface elements forming surfaces for printing of the ink in step a).

### Fluidic Circuit

The fluidic circuit may comprise a channel and/or a chamber, the channel or chamber being contiguous with the solid element along the fluid flow path.

The fluidic circuit may be a microfluidic circuit. The fluidic circuit may comprise at least one microchannel and/or at least one microfluidic chamber. The solid element is preferably contiguous with a microchannel on the fluid flow path. The presence of a microfluidic circuit allows small volumes to be treated, thereby reducing the analysis time, the consumption of liquid, and consequently the cost.

The fluidic circuit may comprise two channels, each fluidically connecting one end of the solid element, with the fluid flow path being defined from one microchannel to the other, passing through the solid element.

The fluidic surface may extend in a plane of extension substantially parallel to the printing surface.

At the junction with the solid element, the fluidic circuit may have a cross section substantially equal to the cross section of the solid element to which it is attached. As a variant, at the junction with the solid element, the fluidic circuit may have a cross section greater than the cross section of the solid element to which it is attached. For example, the fluidic circuit may comprise a channel extending along the plane of extension on the support and comprising, at the junction with the solid element, a vertical extension for attaching the end of the solid element encapsulated in the crosslinked polymer. In this case, the height of the channel at the level of the end of the solid element may be greater than or equal to the sum of the height of the end of the solid element to which it is attached and the height of raising of the solid element relative to the support.

### Solid Element

The solid element may be disposed above the support, with or without contact with the latter. The solid element may be disposed in contact with the support, on blocks arranged on a substrate, or without contact with the latter, on one or more continuous printing portions.

The solid element may extend on the fluid flow path such that the fluid flow path crosses the solid element from an entry point to an exit point, the entry point and the exit point being spaced apart by a distance greater than or equal to 0.5 mm, more preferably greater than or equal to 1 mm, more preferably still greater than or equal to 2 mm. The entry point and the exit point are preferably spaced apart by a distance greater than or equal to 10%, more preferably 50%, more preferably still the entirety of the largest dimension of the solid element. The entry point and the exit point may be on opposite faces of the solid element, in particular at opposite ends of the solid element.

The straight line between the entry and exit points of the fluid flow path preferably extends parallel to the printing surface of the support.

The solid element may be arranged on the fluid flow path such that the straight line connecting the entry and exit points of the fluid flow path in the solid element extends along a median axis of the solid element.

The solid element may have a largest dimension, transversely to the straight line connecting the entry and exit points of the fluid flow path in the solid element, in particular a thickness taken perpendicularly to the plane of extension of the support, of less than or equal to 10 mm, more preferably less than or equal to 5 mm, more preferably still less than or equal to 2 mm, more preferably still less than or equal to 1.5 mm, more preferably still less than or equal to 1 mm. The solid element may have a largest dimension, transversely to the straight line connecting the entry and exit points of the fluid flow path in the solid element, in particular a thickness taken perpendicularly to the plane of extension of the support, of greater than or equal to 20 μm (microns), more preferably greater than or equal to 50 μm, more preferably still greater than or equal to 100 μm, preferably greater than or equal to 200 μm.

The solid element is preferably cylindrical with a polygonal, oval, triangular or circular base, in particular rotationally cylindrical.

The solid element may be elongated along a rectilinear or non-rectilinear axis of elongation, and may have a length of greater than or equal to 0.5 mm, more preferably greater than or equal to 1 mm, more preferably still greater than or equal to 2 mm, and/or of less than or equal to 10 cm, more preferably less than or equal to 5 cm. The axis of elongation may extend on a plane.

The fluid flow path preferably crosses the solid element over its entire length.

The solid element is preferably cylindrical with a diameter of less than or equal to 10 mm, more preferably less than or equal to 6 mm, and/or with a diameter of greater than or equal to 0.02 mm and/or with a length of greater than or equal to 0.5 mm, more preferably greater than or equal to 1 mm, more preferably still greater than or equal to 2 mm.

The solid element may have an aspect ratio, defined as the ratio of its length to its largest transverse dimension, of greater than or equal to 0.2, more preferably greater than or equal to 0.4, more preferably greater than or equal to 1 and/or less than or equal to 1000, more preferably less than or equal to 500, more preferably still less than or equal to 100, more preferably less than or equal to 50, more preferably still less than or equal to 20.

The solid element may be arranged on the support such that the fluid flow path crosses the solid element over a length greater than the thickness of the solid element, the thickness being taken perpendicularly to the printing surface.

### Hollow Element

The solid element may be hollow, the open ends at the two ends of the hollow of the solid element being on the fluid flow path and the central axis of the hollow extending along the fluid flow path. The central axis of the hollow may be rectilinear or curved. In the case of a hollow solid element, the fluid flow path may be maintained in the hollow by plugging of the two ends by a protective agent prior to the addition on the support, or by the ink of the fluidic circuit attached to the hollow end of the solid element during step a).

The solid element may be a tube or a capillary made of silica or of glass or of any other material compatible with the ink and the polymer used in the crosslinking. As a variant, the solid element is a hollow element other than a tube or a capillary. It may be a fluidic junction, in particular a Y, T or X junction, a valve, a gate or a sheath, or a hollow element of any other form.

The capillary may have a diameter of less than or equal to 2 mm.

### Porous Element

The solid element is preferably porous.

The solid element preferably comprises a porous monolith, in particular having hierarchical porosity, meaning that it has at least two orders of magnitude of pore sizes, preferably macropores as described above, formed during a step of forming the sol-gel matrix, and mesopores as described above, formed during a step of controlled generation of mesopores. A porous monolith of this kind exhibits effective exchange of surface area between the fluid traversing it and its substance, and minimizes the distances to be covered by diffusion. Furthermore, this enables the porous monolith to be given flexibility, while reducing risks of breakage.

The solid element preferably comprises a self-supporting porous monolith. Self-supporting means that the porous monolith is stable by virtue of its own rigidity and has no need for any support to be stable enough to be handled.

It may be disposed bare on the support. Disposed bare on the support means that the porous monolith comprises no additional shell before it is disposed on the support, and in particular comprises no heat-shrinking sheath or is not received in a conduit. Conversely, it may be impregnated with the protective agent as described above.

As a variant, the solid element comprises a porous monolith and a protective outer sheath for the porous monolith that is open at the entry point and at the exit point of the fluid flow path, the ink being contiguous with at least one open end of the tube or the capillary in step a) of the method. The porous monolith and the outer sheath are preferably configured such that the fluid flow path crosses the porous monolith over a distance of at least 10%, more preferably at least 50%, more preferably still the entirety of the straight line between the entry point and the exit point in the porous monolith on the fluid flow path.

The protective outer sheath may be a heat-shrinking sheath. The method may comprise inserting the porous monolith into the heat-shrinking sheath and heating the sheath to shrink it on the porous monolith. This allows the porous monolith to have a shrunken sheath thereon that is adjusted to said monolith and ensures that the fluid flow path does indeed traverse the porous monolith.

As a variant, the outer sheath is rigid. It may take the form of a tube or capillary. In this case, preferably, the porous monolith is formed directly in the outer sheath, in particular by the sol-gel method described below. In the case of a capillary, the diameter of the capillary is preferably less than or equal to 2 mm.

The porous monolith may comprise macropores, macropores in particular with a size of greater than or equal to 50 nm. The macropores may have a size of less than or equal to 30 μm.

The porous monolith may comprise mesopores, in particular with a size of less than or equal to 50 nm, more preferably of between 2 and 50 nm. The pores are preferably connected to one another in the porous monolith.

The porous monolith may have a substantially uniform structure throughout its volume.

The porous monolith may exhibit a pore surface functionalization. The surface of the pores in the porous monolith may be covered with compounds such as hydrophobic hydrocarbon ligands (for example, octadecyl ligands) or such as hydrophilic ligands, for instance 2,3-dihydroxypropyl derivatives. The ligands of such modified porous monoliths may be further modified using known procedures. Porous catalysts or enzyme supports may be prepared by adding enzymes, for example glucose isomerase, or catalytic metal elements, for example platinum and palladium.

### Method for Forming the Porous Monolith

The porous monolith is preferably formed by a sol-gel method. A sol-gel method means a method implemented using precursors comprising alkoxides of formula M(OR)ₙ or R′—M(OR)ₙ₋₁ or else sodium silicates or titanium colloids, M being a metal, a transition metal or a metal alloy, in particular silicon, and R or R′ being alkyl groups, and n being the oxidation state of the metal. In the presence of water, the alkoxy groups (OR) are hydroly zed, forming small particles with a size of generally less than 1 nanometer. These particles undergo aggregation to form clusters which remain in suspension without precipitating, and form the sol. The increase of the clusters and condensing thereof increases the viscosity of the medium and forms what is called the gel. The gel may then continue to develop during an aging phase, during which there is a densification of the polymeric network present within the gel. The gel subsequently shrinks, evacuating the solvent from the polymeric network formed, in a step referred to as syneresis. The solvent then evaporates, in a so-called drying step, leading to a porous glass-type solid material, giving a porous monolith. The steps of syneresis and drying may be concomitant. A method of this kind produces a porous monolith having controlled characteristics, in particular of porosity and pore size distribution. It also produces a wide variety of forms.

The method preferably comprises the formation of the porous monolith by a manufacturing method comprising:
the formation of a sol comprising a sol-gel precursor in aqueous solution and, preferably, a pore former,
the at least partial filling of an enclosure and of at least one mold contained in the enclosure with sol formed beforehand, the mold comprising at least one opening opening into the sol after filling with sol,
the formation of a sol-gel matrix in the enclosure from the sol,
the extraction of the mold with the sol-gel matrix contained in the mold from the enclosure, and
the formation of a porous monolith from the sol-gel matrix, where the sol, the sol-gel matrix and the porous monolith are formed by a sol-gel method.

The method may comprise extracting the sol-gel matrix from the mold before or after the formation of the porous monolith.

The presence of at least one opening in the mold beneath the sol level after filling allows the mold to be filled with the sol during the filling step and allows the fluid flow of the sol between the sol contained in the mold and the sol contained in the enclosure during the rest of the method. Producing a large sol-gel matrix in the enclosure and extracting a part of this matrix included in a mold during the formation of the matrix makes it possible to escape the edge effects which appear in previously described methods, by producing the sol-gel matrix in a container which is always the same size. A method of this kind allows porous monoliths, self-supporting in particular, having similar textural properties over an extended range of diameters to be manufactured without having to re-optimize, let alone modify, the formulation of the initial mixture. It also provides access to a wide variety of forms and aspect ratios for the monoliths, but also to varied and reproducible controlled internal structures, in particular of porosity and of pore size distribution. The structures obtained are particularly homogeneous and hence guarantee a uniformity of resistance to mechanical stresses. This may prove useful, for example, for preventing breakages when pressure is exerted on the monolith as it is integrated into the fluidic conduit, in particular when it is encapsulated in a heat-shrinking fluidic conduit.

The sol may be formed by stirring a solution comprising the sol-gel precursor, preferably the sol-gel precursor and the pore former, in particular for a time of greater than or equal to 5 min, more preferably greater than or equal to 10 min, more preferably still greater than or equal to 15 min. The stirring time may be less than or equal to 3 h, more preferably less than or equal to 2 h. During stirring, the temperature may be controlled at a substantially constant predetermined value, in particular of between 0° C. and 90° C., more preferably between 0° C. and 50° C.

Filling may be accomplished without presence of air bubbles and/or gradients in chemical composition and/or temperature of the solvent in the enclosure and the mold or molds.

The formation of the sol-gel matrix may comprise condensation to form a gel and optionally at least partial aging to densify the gel.

The sol-gel matrix is preferably formed in the enclosure without drying of the sol-gel matrix.

The formation of the sol-gel matrix may be accomplished in the same way in the enclosure and the mold. The total porosity and the pore size are preferably substantially uniform in the enclosure and the mold or molds.

The extraction of the mold with the matrix it contains from the enclosure may comprise extracting a block of the sol-gel matrix containing the mold from the enclosure and extracting the mold and the sol-gel matrix it contains from the block extracted previously. The extraction of the mold or of each mold from the block may be accomplished by cutting the sol-gel matrix flush with the corresponding mold or breaking the sol-gel matrix surrounding the mold or molds. As a variant, the extraction of the mold or of each mold with the matrix it contains may be accomplished by withdrawing the corresponding mold from the sol-gel matrix surrounding it, after extraction of the block as described above, or directly in the enclosure without prior extraction of the block, in particular when the corresponding mold is only partly immersed in the sol-gel matrix.

The extraction of the sol-gel matrix contained in the or each mold may be accomplished by means of controlled pressure on said sol-gel matrix, for example by direct pressure with a solid whose size is less than that of the mold, or by pressure of a gas at controlled flow rate, or by opening of the or each mold, in particular by cutting of the or each mold or separating two parts of the or each mold from one another. The mold or molds may be in the form of two parts which can be mutually moved, in particular which are separable or can be moved relative to one another by virtue of a hinge.

The mold containing the sol-gel matrix may be immersed in a liquid during the step of extracting the sol-gel matrix contained in the mold. This facilitates the extraction of the sol-gel matrix.

The formation of the porous monolith may comprise controlled generation of mesoporosity in the sol-gel matrix to form a sol-gel matrix of hierarchical porosity after extraction of the mold from the enclosure, and before the formation of the porous monolith from the sol-gel matrix of the mold. Controlled generation of mesoporosity may be accomplished by immersing the sol-gel matrix, extracted or not extracted from the or each mold, in an aqueous solution for generating the mesoporosity, comprising an agent for dissolving the sol-gel matrix and/or a precursor of an agent for dissolving the sol-gel matrix. The dissolving agent may be ammonium hydroxide, for example at a concentration of 1 M, sodium hydroxide, or hydrofluoric acid or mixtures thereof. The dissolving agent precursor for the sol-gel matrix may be urea or compounds bearing amide functions, in particular formamide, acetamide, N-methylformamide (NMF) and mixtures thereof. The concentration of dissolving agent and/or of dissolving agent precursor is preferably such as to enable the localized dissolution of the sol-gel matrix or matrices so as to form mesopores in said matrix or matrices without entirely dissolving the sol-gel matrix or matrices.

The formation of the porous monolith may comprise at least partial aging to densify the sol-gel matrix, in particular when aging has not taken place completely before.

The formation of the porous monolith may comprise drying of the sol-gel matrix, extracted or not extracted from the mold, to form a dried sol-gel matrix, where appropriate after the generation of mesopores. The drying step may be accomplished in a stream of air or inert gas, in particular in dinitrogen, argon or carbon dioxide, helium, or even dioxygen or dihydrogen.

The formation of the porous monolith may comprise a heat treatment of the sol-gel matrix or matrices, extracted or not extracted from the or each mold, in particular after drying. The heat treatment may be accomplished in a closed container in a stream of air or inert gas, in particular in dinitrogen, argon or carbon dioxide, helium, or even dioxygen or dihydrogen, and by gradual heating followed by holding at the final temperature for a predetermined time. The gradual heating may be an increase of 0.5° C./min until a temperature is reached of greater than or equal to 300° C., more preferably greater than or equal to 340° C., for example substantially equal to 350° C., to give a porous monolith. The final temperature may be held for more than 1 h. This allows the structure of the monolith to be stabilized and the organic residues resulting from synthesis to be removed.

As a variant, the porous monolith is formed directly in a mold in which the sol is inserted and is extracted from the latter, in particular by the technique referred to above.

The method may comprise post-fabrication modifications of the porous monolith, in particular the functionalization of the surface of the porous monolith, in particular before or after placement thereof on the support, in particular after extraction of the ink and/or the protective agent. The surface of the porous monolith may be covered with molecules as described above.

### Ink

The ink and/or the protective agent may be selected from the following:
linear glycols having the generic molecular formula C₂ₙH₄ₙ₊₂O₂ in which n is a positive integer greater than or equal to 1, preferably such that n=3, 4 or 5;
cyclohexanediol;
biphenyl;
tri(cyclohexyl)methane;
alcohols of molecular formula CₙH₂ₙ₊₂O in which n is a positive integer greater than or equal to 1, preferably such that n=10, 11 or 12;

and mixtures thereof.

The ink and/or the protective agent may have a viscosity of less than or equal to 30mPa·s⁻¹, in particular in the case of printing by inkjet, measured at a pressure of 1013.25 hPa, at a temperature of 22 C and at a sheer rate of 1 s⁻¹. The viscosity may be measured using a cone/plate viscometer, in particular using an Anton Paar rheometer, Physica MCR 30 model, or a similar device.

The protective agent is preferably wetting in character with respect to the material of the solid element. This allows the porous solid element to be filled spontaneously by contact, by simple capillarity. Wetting means that a drop disposed on the material of the solid element has a contact angle of less than 90°, more preferably less than or equal to 45°.

As a variant, the protective agent is non-wetting in character with respect to the material of the solid element, meaning that a drop disposed on the material of the solid element has a contact angle of greater than 90°. In this case, the method may comprise applying an overpressure during the application of the protective agent to the porous solid element in order to counterbalance the Laplace pressure, in particular an overpressure which is dependent on the pore size and the surface tension, in particular of between 1 mbar and 1 bar.

### Device

The device comprises a fluid entry and/or a fluid exit, the fluid flow path extending from the fluid entry to the fluid exit in the device. The fluid entry and the fluid exit are preferably separate. The fluid entry and/or exit may comprise a piercing in the thickness of the polymer, connected fluidically to the fluidic circuit. As a variant, the fluid entry and/or exit are/is formed by the fluidic circuit and/or the solid element, in particular the fluidic circuit and/or the solid element opening out outside the polymer.

The device may comprise a plurality of solid elements which are porous or are fluidically connected to one another in series or in parallel by one or more portions of the fluidic circuit. They are preferably connected to one another in series. The solid elements may have substantially the same dimensions, structure and/or porosity, or as a variant may differ in one of their properties, in particular their dimension, structure and/or porosity.

The device may form a functional unit comprising a functional module, a fluid entry and exit of the device. The functional unit is configured to be connected in series via its fluid entry and/or exit to one or more adjoining fluidic units to form a complex fluid flow structure. The one or more adjoining fluidic units may be identical or, preferably, different, at least in their function.

### BRIEF DESCRIPTION OF THE DRAWINGS

FIG. 1 represents the various steps of the manufacturing method according to the invention,

FIG. 2 represents schematically a variant fluid flow device,

FIG. 3 represents schematically a variant fluid flow device,

FIG. 4 represents schematically a variant fluid flow device,

FIG. 5 represents schematically in section a variant of a detail showing the solid element of a fluid flow device,

FIG. 6 represents schematically in section a variant of a detail showing the solid element of a fluid flow device,

FIG. 7 represents schematically in section a variant of a detail showing the solid element of a fluid flow device,

FIG. 8 represents schematically in section a variant of a detail showing the solid element of a fluid flow device,

FIG. 9 represents schematically a method for manufacturing a porous monolith, and

FIG. 10 represents schematically a variant method for manufacturing a fluid flow device on a fluid flow path.

### DETAILED DESCRIPTION

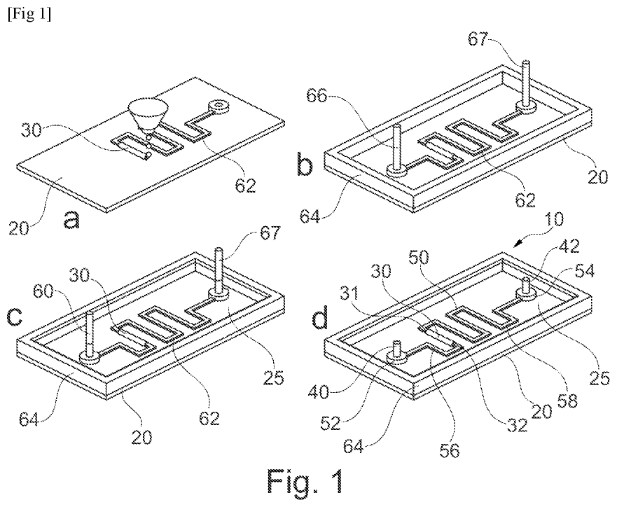

FIG. 1 illustrates the method for manufacturing a fluid flow device 10 on a fluid flow path.

The device to be obtained, illustrated in step d. of FIG. 1, comprises a rigid substrate 20, made for example of glass or plastic, on which a layer 25 made of a crosslinked polymer extends.

Within the layer 25 is a hollow or porous solid element 30 connected to two entries/exits 40 and 42 by a fluidic circuit 50. The solid element 30 preferably is cylindrical and is connected to the entry/exit by its two opposite ends 31 and 32, forming entry and exit points of the fluid flow path through the solid element 30, such that a fluid flowing in the device crosses right through the solid element 30 over its entire length.

The two entries/exits 40 and 42 may form vertical fluidic conduits through the polymeric layer 25, made for example of PDMS, for fluidically connecting the outside of the device to the fluidic circuit 50 extending within the polymeric layer 25, in particular at the junction between the substrate 20 and the polymeric layer 25. The fluidic circuit 50 comprises two chambers 52 and 54, in which the two exits/entries 40 and 42 open out, and two channels 56 and 58 connecting the chambers 52 and 54 to the solid element 30. The various open elements of the device allow a fluid to flow between the two entries/exits 40 and 42 through the fluidic circuit 50 and the solid element 30.

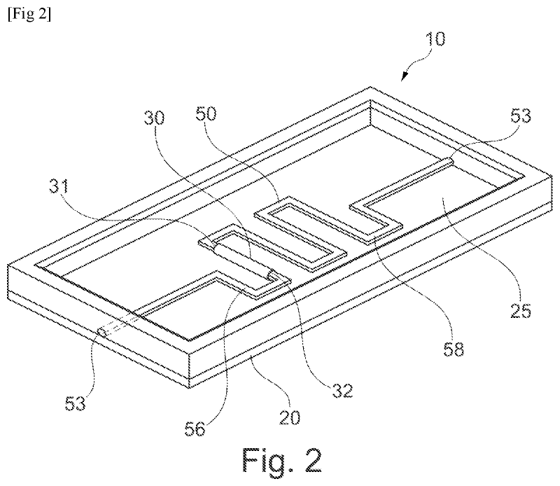

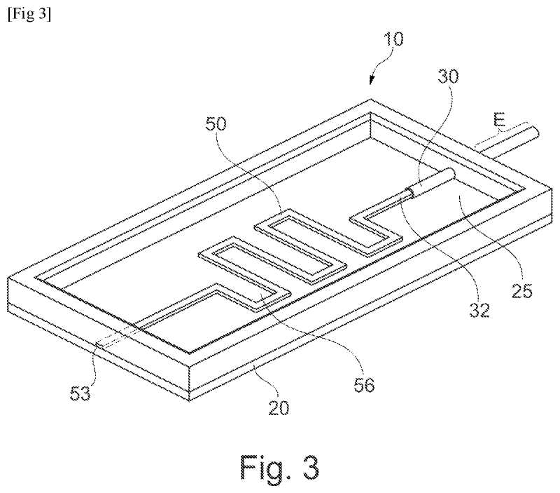

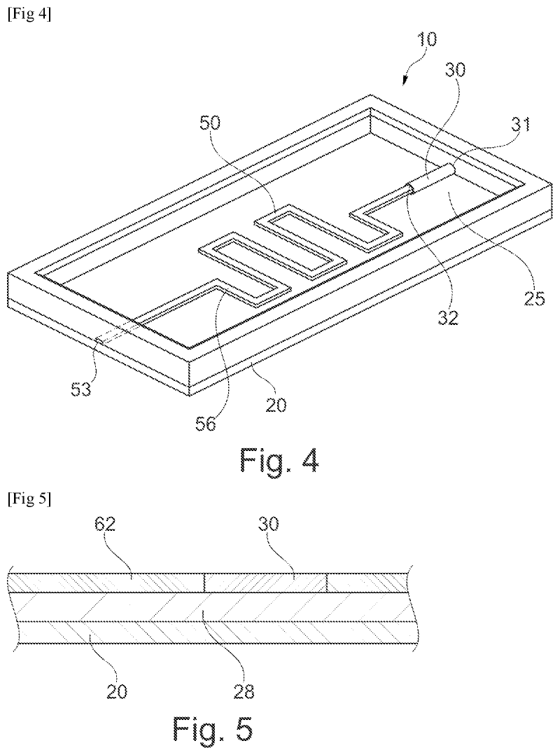

It could be different, however: at least one of the two entries/exits 40 and 42, more preferably the two entries/exits, could extend laterally from the polymeric layer 25 and be formed by an end 53 and 55 of the fluidic circuit 50 opening out on a lateral surface of the polymeric layer 25, as is illustrated in FIG. 2, or by a part of the solid element 30 extending through a surface of the polymeric layer 25, as illustrated in FIG. 3, or flush on the surface of the polymeric layer 25, as illustrated in FIG. 4. As a variant (not illustrated), the device could comprise only one entry, connected fluidically to the fluidic circuit 50, and have no exit. The fluidic circuit may form a loop.

In the example illustrated in FIG. 1, the fluidic circuit 50 and the solid element 30 are arranged at the interface between the substrate 20 and the polymeric layer 25.

It could, however, be different, and the fluidic circuit 50 and/or the solid element 30 could be arranged within the polymer layer 25, with the device comprising or not comprising the rigid substrate 20.

The device may comprise a plurality of hollow or porous solid elements integrated within the polymeric layer 25.

The fluid flow path in the device is preferably planar in a plane parallel to the surface of the substrate 20. As a variant, the fluidic circuit may have a three-dimensional structure such that the fluid flow path in the polymer is also in three dimensions.

The solid element may be a tube or a hollow capillary. As a variant, it may be a porous monolith having simple or hierarchical porosity. In this case, it is preferably manufactured by a sol-gel method as described below.

The device may form a functional unit, which may be connected to a system of larger scale, in particular having other—different or identical—functional units, and comprising or not comprising a hollow or porous solid element.

It is important to have the solid element integrated in the configured device so that the solid element retains its integrity and its properties, in particular its porosity in the case of a porous element with fluid flow within said element, and so that the fluid flows in the device along a fluid flow path which passes within the solid element and not around it. It is also important that the connection between the solid element 30 and the fluidic circuit enables effective flow of the fluid between the two. The problem is substantial whether the solid element is porous or hollow, owing to the presence within the polymeric layer of a fluidic junction between the solid element and the fluidic circuit which could be blocked by the polymer during manufacture, and/or of an interface between the polymeric layer and an at least partially open surface of the solid element, which could allow the polymer to penetrate the porous element during manufacture and so block the flow of the fluid in the solid element. This problem is exacerbated in the case of a self-supporting porous solid element integrated in the device without a protective sheath, owing to the presence of pores which open out over its entire surface and allow the polymer to penetrate when the polymeric layer is formed.

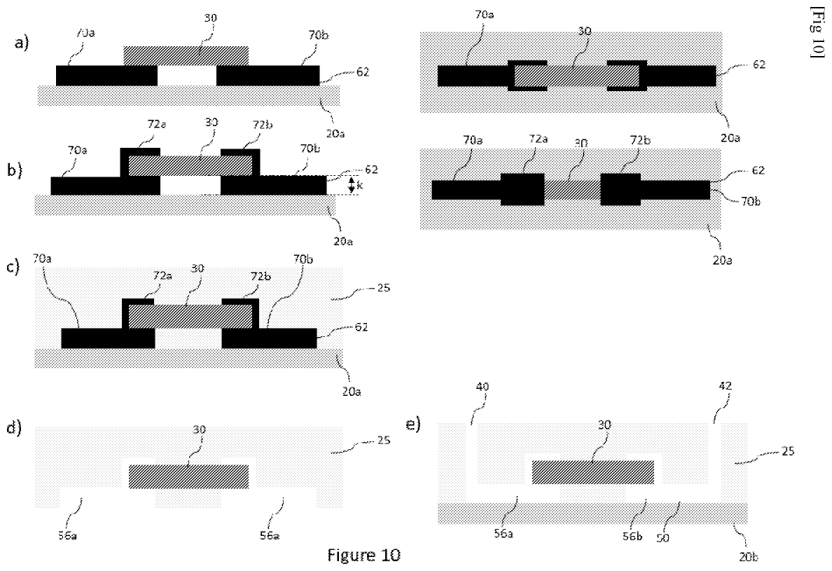

To form the device described, the method, in step a. illustrated in FIG. 1, comprises disposing the hollow or porous solid element 30 on the upper flat surface of a support consisting of the substrate 20, at a predetermined position, then printing the course 62 of the fluidic circuit on the support, including the fluidic chambers 52 and 54, with an ink which may be selected from linear glycols having the generic molecular formula C₂ₙH₄ₙ₊₂O₂in which n is a positive integer greater than or equal to 1, preferably such that n=3, 4 or 5, cyclohexanediol, biphenyl, tri(cyclohexyl)methane or alcohols of molecular formula CₙH₂ₙ₊₂O in which n is a positive integer greater than or equal to 1, preferably such that n =10, 11 or 12. As a variant, the course 62 of the fluidic circuit is printed before the positioning of the solid element 30 on the support. The course 62 is printed and the solid element 30 is disposed such that, at the junction between the solid element 30 and the ink, the ink and the solid element 30 are in contact, here at the two ends 31 and 32 of the solid element 30. The ink may penetrate the solid element 30 to fill it if it is not filled beforehand by a protective liquid or on the surface, at the junction, over a certain distance. By means of such contact/penetration, it is possible to prevent there being polymer interfering at the junction between the two, which would prevent subsequent fluid flow. As a further variant, the course 62 of the fluidic circuit is printed in a number of steps, with a first printing taking place before the positioning of the solid element 30 on the support and a second printing after, as is illustrated in FIG. 10. This may make it possible to have an effective junction between the course and the solid element and to position the solid element on one or more layers of ink before the second printing.

Printing may be accomplished by inkjet, using a printing nozzle and a liquid ink having a viscosity of less than or equal to 30 mPa·s⁻¹. The distance between said printing nozzle on the one hand and the support on the other hand may be between 0.5 mm and 20 mm. The size of an ink drop ejected by said printing nozzle may be between 10 μm and 100 μm. The rate of ejection of ink drops by said nozzle may be between 50 Hz and 5 kHz. The support on the one hand and said printing nozzle on the other hand may be adapted to allow a relative displacement of one relative to the other at a controlled relative displacement velocity, of between 1 mm/s and 100 mm/s. As a variant, the ink is printed by means of a syringe. The distance between one end of the syringe via which the ink is dispensed, on the one hand, and the support on the other hand may be between 0.1 mm and 1 mm. The flow rate of ink dispensed by the end of said syringe may be between 0.01 nl/s and 10 nl/s. The support on the one hand and said syringe end on the other hand may be adapted to allow a relative displacement of one relative to the other at a controlled relative displacement velocity, of between 0.1 mm/s and 10 mm/s.

Depending on the thickness of the course 62 of the fluidic circuit and/or its structure in the polymer, it may be necessary to superimpose a plurality of layers of ink, at least at certain locations, after drying or solidification of each layer. This may make it possible in particular to produce a three-dimensional structure of the course 62.

The ink is subsequently left to dry or solidify, either spontaneously in view of its nature, or by heating or cooling.

The ink may optionally be annealed at a temperature lower than the extraction temperature of the ink at equivalent pressure. Such annealing allows the roughness of the course deposited to be reduced. Indeed, when the ink has solidified, and in spite of the care taken with the deposition conditions, it may be noted that the surface of the ink in solid form may exhibit significant roughness. This roughness, consequently, may transfer to the polymer walls of the fluidic circuit. The roughness may have a not insignificant effect on the flow conditions in the device and, consequently, may give rise to head losses and/or undesirable heat exchange, or may modify the analytical conditions, depending on the architecture of the device.

After drying or solidification of the ink and optionally annealing, the method, as illustrated in step b. of FIG. 1, comprises positioning a mold 64 on the substrate to allow the polymer to be molded on the fluidic circuit 20 and the solid element 30. The method may also comprise positioning additional elements, in this case tubes 66 and 67 to form the two entries/exits 40, 42 in the thickness of the polymer.

As illustrated in step c. of FIG. 1, the polymer in the liquid state 25 is subsequently poured into the mold to cover the ink forming the course 50 of the fluidic circuit and the solid element 30. It is subsequently solidified by crosslinking. Crosslinking may be facilitated by a crosslinking agent or a photoinitiator present in the polymer. As a variant, the polymer may comprise a solvent, with the polymer crosslinking after evaporation of the solvent. Crosslinking may be accomplished by heating to a temperature lower than the extraction temperature of the ink at equal pressure. The polymer 25 is such that it is not miscible with the ink.

Lastly, in step d. of FIG. 1, the ink is extracted from the polymer 25 by vaporization, in particular by sublimation or by liquefaction and then vaporization, by heating the device and/or subjecting the device to a pressure differential. The optional removable additional elements, in particular the entry/exit tubes 40 and 42, are withdrawn before or after extraction of the ink.

The device is then washed by passing a liquid from the entry to the exit in the device.

However, the invention is not limited to an extraction technique of this kind. Other techniques may be contemplated, in particular the withdrawal of the support to expose the ink in the polymer and the dissolution of the ink by a solvent, alcohol in particular, and/or the vaporization or sublimation of the residues of ink before an identical or different support is replaced.

The extraction of the ink after crosslinking allows the fluidic circuit 50 to form in the polymer 25.

The mold 64 may be retained or withdrawn after solidification.

In the case of a hollow solid element 30, the hollow ends of the solid element may be covered by the ink such that the polymer 25 is unable to penetrate the hollow solid element 30. In this case, the thickness of the ink is greater than or substantially equal to the height of the solid element 30. As a variant, the hollow of the solid element may be plugged at the entry and/or exit or filled with a protective agent, which in particular is identical to or different from the printing ink, before the hollow element is disposed on the support. Said agent may be extracted at the same time as the ink by the same technique. In that case, the thickness of the ink is relatively unimportant, and may for example be less than the height of the solid element, since the hollow is protected from the penetration of the polymer.

In the case of a porous solid element 30, the solid element 30 may be covered over its entire surface or filled at least on the fluid flow path with a protective agent, which in particular is identical to or different from the printing ink, before being disposed on the support to prevent the polymer entering the element. Said agent may be extracted at the same time as the ink by the same technique. As a variant, the polymer 25 is crosslinked sufficiently rapidly to prevent the polymer 25 from plugging the solid element in every section via which the fluid flow path runs, so as to ensure the possibility of fluid flow within the solid element 30.

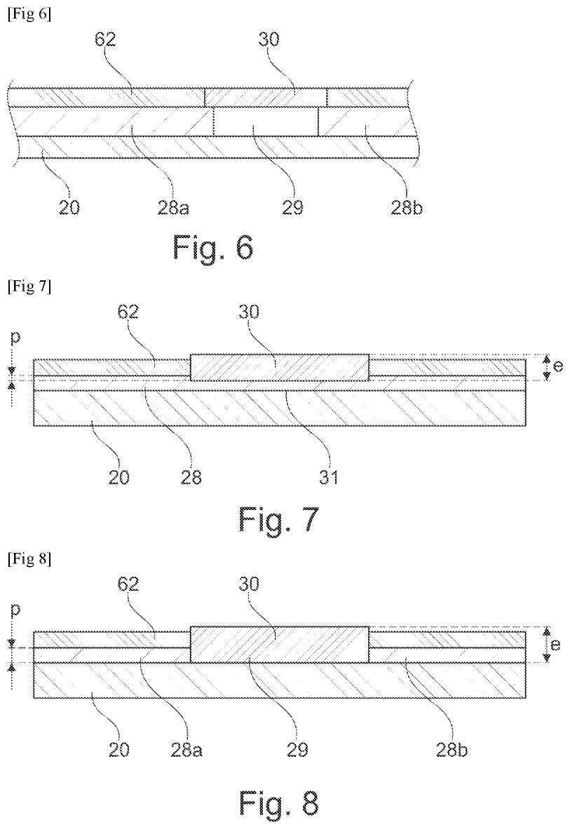

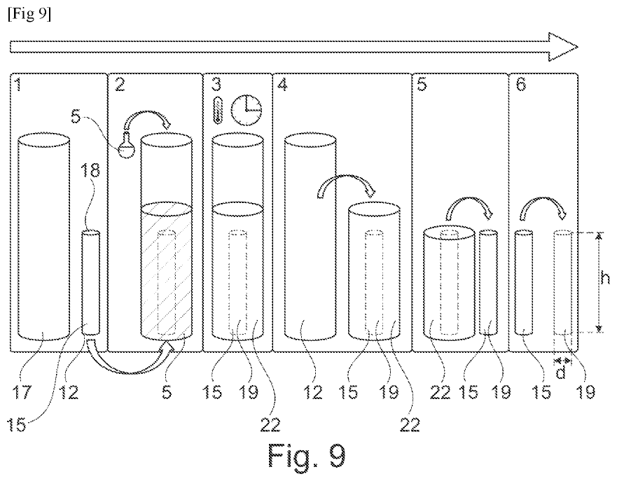

As a variant, the support, on the substrate 20, may comprise one or more support or receiving elements 28 placed on the substrate. The element or elements may be made of a crosslinked polymer having a flat outer surface, in particular of a polymer identical with that of the polymeric layer 25. The support may comprise a support element 28 forming a support layer for the printing and the deposition of the solid element 30, as illustrated in detail in section in FIGS. 5 and 7. A support layer of this kind may be placed on the substrate 20 or be formed directly on the substrate by pouring into a mold on said substrate and crosslinking. The support layer 28 may form a flat surface, as illustrated in FIG. 5, or may have one or more surface reliefs, in particular a cavity 31 for receiving the solid element 30, as illustrated in FIG. 7. In this latter case, the cavity 31 for receiving the solid element 30 has a depth p of less than 50% of the dimension e of the solid element 30 in the direction of the depth of the cavity. In a variant illustrated in FIGS. 6 and 8, the support comprises a plurality of support or receiving elements 28a and 28b which are disposed on the substrate 20 and are spaced apart by a nonzero distance to form a cavity 29. As illustrated in FIG. 6, the solid element 30 may be placed straddling the two support elements 28a and 28b which are spaced apart by a distance d which is less than the length L of the solid element 30, with the course 62 of the fluidic circuit being printed on the support elements 28a and 28b. In this embodiment, when the polymer 25 is poured, it surrounds the solid element 30 in the free cavity 29 between the two support elements 28a and 28b. In this way, the solid element 30 is encapsulated in a monolithic polymeric layer, so reducing the risk of breakage at the junction with the substrate 20 when the substrate 20 is withdrawn, in particular in the case of a solid element having a large transverse size. In a variant illustrated in FIG. 8, the solid element 30 is received in the cavity formed between the receiving elements 28a and 28b, the cavity having a depth p which is less than the dimension of the solid element in the direction of the depth of the cavity. It preferably comes into contact with the receiving elements 28a and 28b in the cavity 29 via its two longitudinal ends, such that the ink deposited on the receiving elements is in contact with the solid element 30.

The substrate 20 may be withdrawn after extraction of the ink, more particularly in the case where the fluidic circuit 50 and the solid element 30 are not in contact with the substrate 20, in particular owing to the presence of the one or more support elements 28.

In the examples illustrated, the fluidic circuit is primarily composed of channels. It goes without saying that the circuit can have any structure compatible with the manufacturing method with the printing of the ink. It may in particular comprise one or more fluidic chambers or may integrate solid complementary elements other than the solid element, especially interconnect elements to allow the fluid to flow in the fluidic circuit, in particular to connect the fluidic circuit to the fluid entry or exit or to connect the device to another—identical or different—device, and/or elements for arrangement of the solid element on the support, especially blocks disposed under the solid element, and/or elements for functionalization of the fluidic circuit, especially functionalized or unfunctionalized beads extending in a portion of the fluidic circuit. These complementary elements may remain in the final fluidic circuit or may serve only for the formation of channels, for example, during manufacture.

In the example illustrated, filling with the polymer and crosslinking thereof take place in one operation. This step could be carried out in multiple successive steps of partial filling and crosslinking.

FIG. 7 illustrates the various steps of one example of a method for manufacturing the porous monolith.

The method comprises a first step, not illustrated, of forming an aqueous solution of a pore former and a sol-gel precursor and optional additives, in particular an acid and/or an agent for dissolving the matrix.

The pore former may be selected from water-soluble polymers, especially polyethylene glycol (PEG), poly(acrylic acid), sodium poly(styrenesulfonate) and poly(ethyleneimine).

The one or more water-soluble polymers may have a molecular weight of between 1000 and 100 000 daltons, preferably between 5000 and 50 000 daltons, more preferably still between 5000 and 30 000 daltons.

The concentration of pore former, in particular of PEG, may be between 0.015 g and 0.35 g per ml of sol, preferably between 0.02 and 0.2 g per ml of sol. These values are linked to the concentration of sol-gel precursor, in particular of tetramethoxysilanes (TMOS), according to values of 0.03 to 1 g of pore former, in particular of PEG, per ml of sol-gel precursor, in particular of tetramethoxysilanes (TMOS), preferably according to values of 0.06 to 0.6 g of pore former, in particular of PEG, per ml of sol-gel precursor, in particular of tetramethoxysilanes (TMOS). It is selected depending on the size of the macropores desired for the final porous monolith.

The sol-gel precursor may be selected from alkoxides, especially hydrolysable and condensable organometallic compounds, especially zirconium alkoxides, in particular zirconium butoxide (TBOZ) and zirconium propoxide (TPOZ), titanium, niobium, vanadium, yttrium, cerium, aluminum or silicon alkoxides, in particular tetramethoxysilane (TMOS), tetraethoxysilane (TEOS), tetrapropoxysilane (TPOS), tetrabutoxysilane (TBOS), trimethoxysilanes, in particular methyltrimethoxysilane (MTMOS), propyltrimethoxysilane (PTMOS) and ethyltrimethoxysilane (ETMOS), triethoxysilanes, in particular methyltriethoxysilane (MTEOS), ethyltriethoxysilane (ETEOS), propyltriethoxysilane (PTEOS), aminopropyltriethoxysilane (APTES) and mixtures thereof, for example TMOS. It is also possible to use precursors such as sodium silicates, or titanium colloids, especially if the purity requirements permit this, i.e., are not too high.

The proportion of pore former in the sol and the proportion of sol-gel precursor in the sol are predetermined according to the characteristics, in particular the total porosity and the average size of the macropores, of a sampling of known sol-gel matrices taken just after gelling.

The solution is subsequently stirred for a predetermined time of between 5 min and 3 h, more preferably still between 15 min and 2 h, at a substantially constant controlled temperature of between 0° C. and 90° C., more preferably between 0° C. and 50° C. This stirring step allows the sol-gel method to be initiated to form a sol 5 before phase separation.

The sol 5 is then added in step 2 to a container 12, to at least partially fill said container 12 and at least one mold 15 contained in the enclosure 12.

The mold 15 may be positioned in the enclosure, which is gradually filled with the sol 5 in such a way that the mold 15 fills gradually in the absence of air bubbles or a gradient in chemical composition. Filling may take place until the mold 15 is completely immersed. Partial immersion is also possible. The addition of the mold to the sol 5 contained in the enclosure 12 is also possible.

The enclosure 12 may be configured to contain a plurality of identical or nonidentical molds 15. The enclosure 12 may be cylindrical, as illustrated, or may have any other shape. The enclosure 12 may be made of plastic, in particular of PTFE, PP, PE, PC, PET, PVC, or glass or stainless steel.

The mold or molds 15 comprise two openings 17 and 18 on opposite surfaces of the mold 15, at least one of the two openings 17 extending beneath the level of sol after filling. Such openings allow the mold or molds 15 to be filled by filling of the enclosure 12 containing the mold or molds 15 or by at least partial immersion of the mold or molds 15 in the sol 5 contained in the enclosure 12, and the flow of the sol 5 between the inside and the outside of the mold or molds before complete condensation of said sol. In the example illustrated, the mold or molds 15 are in the form of tubes which are open at their two ends and extend vertically in the enclosure 12, but it could be entirely different: the tube could be oriented differently in the enclosure and/or the mold could have a different shape.

The mold or molds 15 may be contained entirely in the enclosure 12, as is illustrated, or may jut out from said enclosure. In the first case, the mold or molds 15 may be immersed entirely or not in the sol 5 after filling.

The mold or molds 15 may be made of plastic, in particular of PTFE, PEEK, PEP, PE, PP, or polylactic acid, or of glass or stainless steel, in particular of fused silica or borosilicate.

The mold or molds may be made of a porous body.

The mold or molds may be formed by 3D printing or by molding.

The largest transverse dimension of the cavity of the mold or molds 15, in particular the diameter d of this cavity, may be between 13 mm and 0.025 mm.

When the sol 5 has been introduced into the enclosure 12 and the mold or molds 15, condensation is carried out in step 3 in the assembly of the enclosure and the mold. This sol-gel transition may be followed by at least partial aging of the assembly. Through this step it is possible to ensure the formation of uniform macropores of similar kind in the sol-gel matrix 22 formed, irrespective of the shape and size of said matrix.

During the condensation, the temperature may be maintained substantially constant, in particular between 15°and 90° C., preferably 25° and 70° C., for a time of between 10 min and 4 h. The condensation time and the predetermined temperature are dependent on the internal structure of the desired sol-gel matrix and on the stirring time for the initial solution in the step of formation of the sol.

The at least partial aging may last between 30 min and 2 weeks, in particular less than 72 h at ambient temperature. The aging time is preferably short enough to prevent the formation of mesopores and/or micropores.

A bloc 22 of sol-gel matrix containing the mold 15 is then extracted from the enclosure 12 in step 4. In this case where the mold 15 is only partially immersed, this step may be optional, as we will see subsequently.

The mold 15 with the sol-gel matrix 19 which it contains is then extracted from the porous solid in step 5, for example by cutting the sol-gel matrix from the bloc 22 flush with the mold and then withdrawing the mold 15 with the sol-gel matrix 19 it contains, or else by breaking the sol-gel matrix from the bloc 22 around the mold 15. Where immersion was partial, it is possible to withdraw the mold 15 directly with the sol-gel matrix 19 it contains from the block previously extracted or directly from the enclosure 12.

Optionally, the sol-gel matrix 19 is extracted from the mold 15 in step 6 to give a self-supporting monolith. This is carried out by means of a controlled pressure exerted on the sol-gel matrix 19 while holding the mold 15. The pressure may be obtained either with a solid made of plastic or of glass, such as a fused silica capillary, for example, or any other material sufficiently robust and of a size less than that of the mold 15, or with a gas at a controlled flow rate. The extraction operation may be made easier by immersing the assembly of mold 15 and sol-gel matrix 19 in a liquid. It is possible optionally to generate a slight pressure difference by gently tapping the assembly of mold 15 and sol-gel matrix 19 in order to extract the sol-gel matrix 19.

The method may then comprise a step of controlled generation of the mesoporosity. This step may be accomplished by immersing the sol-gel matrix 19 or the mold/sol-gel matrix assembly in a basic solution, for example a 1 M solution of ammonium hydroxide, or by heating the material in water in the presence of a precursor, urea for example, to generate ammonia in situ. It should be noted that in the second technique, it is possible to add ammonium hydroxide. This operation may last for between 0.5 h and 50 h at a substantially constant predetermined temperature of the sol-gel matrix of between 30° C. and 150° C. This step may be carried out on a plurality of sol-gel matrices simultaneously, i.e., in a single bath, obtained from a single block or not.

The resulting pore size is preferably less than or equal to 50 nm, more preferably between 2 and 50 nm.

The sol-gel matrix obtained is subsequently dried. To do this, it is placed in a closed container, in particular an autoclave, to be dried under critical or supercritical conditions, in particular in a stream of air or of inert gas, especially dinitrogen (N₂), for a time of between 10 and 20 h. They are subsequently subjected to a ramp of 0.5° C./min up to 350° C. with a plateau of several hours at this latter temperature and in a stream of inert gas (other gases may be employed).

The outcome is then a monolith which is self-supporting or integrated in a mold, in particular a capillary, which is ready to use.

The porous monolith obtained preferably comprises macropores, i.e., pores having a selected size of greater than or equal to 50 nm, and mesopores, i.e., pores having a selected size of between 2 and 50 nm.

The monolith preferably has a substantially uniform structure throughout its volume.

The porous monolith or monoliths may have an aspect ratio, defined as the height to the largest transverse dimension thereof, of between 0.2 and 100.

The method may comprise post-fabrication modifications of the porous monolith, in particular the functionalization of the inner surfaces of the porous monolith. The functionalization may be carried out by liquid-phase or else gas-phase methods, using organosilanes, particularly chlorosilanes (e.g., octadecyltrichlorosilane) and alkoxysilanes (octadecyltriethoxysilane, aminopropyltriethoxysilane, propyltrimethoxysilane), or else hexadimethylsilazane.

As a variant, the mold or molds may have only one opening. This opening opens into the sol after filling, to allow the sol to flow between the mold and the enclosure.

As a variant, the initial solution may be a “templating” emulsion or solution containing sol-gel precursors.

### EXAMPLE 1

In this example, a self-supporting porous monolith cylindrical in shape with a diameter of about 700 μm and a length of about 15 mm, having macropores of about 2 μm and mesopores of about 15 nm, is integrated into a microfluidic device at the center of a straight fluid flow channel having a diameter of several hundred micrometers, as illustrated in FIG. 7.

The porous monolith was manufactured by a sol-gel method, described below.

A solution is prepared by mixing 0.33 g of PEG with 2 mL of TMOS in 4 mL of 0.01 M acetic acid. The solution is stirred at 0° C. for 30 min to form a sol and then transferred to a polypropylene (PP) container, in which a PTFE tube having a diameter of about 1 mm has been positioned vertically beforehand. Filling is carried out by gradually adding the sol in the enclosure, starting from the lowest point, using a micropipette. The amount of solution added is such that the mold is completely immersed.

The enclosure is placed at a temperature of 40° C., and gelling takes place between 45 and 50 min after transfer to the enclosure. When gelling has taken place, the gel is left to age for 24 h at 40° C. The sol-gel matrix resulting from gelling and aging is then extracted from the enclosure and broken with metal tongs to recover the mold incorporated therein. The monolithic sol-gel matrix encapsulated in the mold is subsequently extracted using a manual pressure exerted by a tube with a diameter of less than 1 mm. For this protocol, this pressure via a solid tube is sufficient to extract the monolith and not weaken the gel.

The resulting sol-gel matrix is rapidly immersed in a 1 M NH₄OH solution, observing a ratio of about 5 between the volumes of basic solution and the volume occupied by the sol-gel matrix.

The resulting matrix is subsequently disposed in an autoclave. The latter is placed in an oven and connected by tubes which allow a flow of gas. The gel is then dried for 12 h under N₂. Finally, a heat treatment is carried out with a ramp of 0.5° C./min up to 350° C. and a plateau of 2 h at this latter temperature.

The self-supporting porous monolith thus obtained is subsequently protected by immersion for about 1 minute in 1,8-octanediol, forming an impregnating ink at 80° C. The impregnated cylindrical monolith is preferably contacted with an absorbent paper to remove the excess liquid, before being placed in a glass dish until the protective liquid present in the porous material has solidified.

A rectangular polydimethylsiloxane (PDMS) substrate is manufactured and disposed on a glass slide.

The impregnated porous monolith is subsequently disposed on the PDMS substrate. On either side of the ends of the porous monolith, 1,8-octanediol is printed in the form of a course of two straight channels with a diameter of less than 0.7 mm on each side of the impregnated porous monolith, the channels being connected to the monolith at each of its ends, and the ink being in contact with the ends of the impregnated porous monolith and being able to mix with the impregnating ink. Printing takes place using a low-volume micropipette or else a printer.

At each free end of the channels, cylindrical holes are formed through the PDMS substrate using a dedicated 0.5 mm PDMS punch. These holes constitute the entries and exits of the future device. The holes are subsequently covered and connected to the ends of the channel by the preceding ink. It is also possible for these holes to be generated during or after the covering and by using means other than a protective ink (for example, addition of elements made of PDMS).

A rectangular PDMS mold which is open on the top and bottom faces and has dimensions less than or equal to those of the substrate is subsequently placed on the substrate to enable the addition of the liquid polymer covering layer while preventing it from spreading.

Liquid PDMS containing a crosslinker is then added to the mold so as to cover the monolith and the ink completely. The PDMS is then crosslinked at 100° C. for 2 h.

The device formed is subsequently placed under vacuum and heated to 100° C. so that the ink present in the material and forming the channels on either side of the porous monolith is able to undergo sublimation and/or evaporation. To finish, the device is washed with a water/ethanol mixture (50/50) and then with pure ethanol before being dried in an oven at 40° C. for 24 h.

The resulting fluidic device allows the flow of fluid from the entry to the exit, passing via the porous monolith.

### EXAMPLE 2

In this example, the substrate is made of glass and the covering layer is made of PDMS, and a porous monolith 5 mm in diameter, obtained by the same sol-gel method as described in Example 1, except for the size of the tube, is placed on two elements made of PDMS forming support elements, which themselves are placed on the glass substrate as illustrated in FIG. 6. The addition of liquid PDMS then allows the formation of the polymeric layer around the porous monolith and ensures effective imperviousness.

The method is carried out as follows.

The porous monolith with a diameter of 5 mm, having macropores of about 2 μm and mesopores of about 15 nm, is protected by immersion for about 1 minute in a protective liquid, 1,8-octanediol, heated to 80° C. The impregnated cylindrical monolith is preferably placed and rolled on absorbent paper to remove the excess liquid, before being placed in a glass dish until the protective liquid present in the porous material has solidified.

A glass slide is used. Two squares of PDMS are placed on the glass slide such that the distance between the two squares is less than the length of the impregnated porous monolith. The porous monolith is disposed straddling the PDMS squares. On either side of the ends of the material, on the two PDMS support elements, 1,8-octanediol is placed so as to form a straight channel with a diameter of less than 0.7 mm which is connected to the impregnated porous monolith by contact at its ends. Placement takes place with the aid of a low-volume micropipette or else a printer.

A rectangular mold based on PDMS and open on the top and bottom faces, with dimensions less than or equal to those of the substrate, is placed on the substrate to enable the formation of the liquid polymer covering layer while preventing it from spreading. Liquid PDMS containing crosslinker is then added to the mold so as to cover the channel and the porous monolith completely. The PDMS is then crosslinked at 100° C. for 2 h.

The device still containing the ink is then placed under vacuum and heated to 100° C. so that the ink present in the material and forming the channel is able to undergo sublimation and/or evaporation. To finish, the device is washed with a water/ethanol mixture (50/50) and then with pure ethanol before being dried in an oven at 40° C. for 24 h.

The glass slide is withdrawn and then, using a 0.5 mm punch for PDMS, cylindrical holes through the PDMS shell are formed on each end of the straight channel. The glass slide may be withdrawn before or after extraction of the ink.

### EXAMPLE 3

This example is described in relation to FIG. 10, illustrating the various steps described below.

In this example, the substrate is made of glass.

A porous monolith with a diameter of 800 μm obtained by the same sol-gel method as described in Example 1, except for the size of the tube, is formed. The porous monolith has macropores of about 2 μm and mesopores of about 15 nm, and is protected by immersion for about 1 minute in a protective liquid, 1,8-octanediol, heated to 80° C. The impregnated cylindrical monolith is preferably placed and rolled on absorbent paper to remove the excess liquid, before being placed in a glass dish until the protective liquid present in the porous material has solidified.

In step a), illustrated by the device in section on the left and in plan view on the right, a first printing of 1,8-octanediol is carried out on an initial support 20a to form two continuous portions 70a and 70b of ink which are separate from one another. The printing is accomplished by means of a low-volume micropipette or else a printer, in one or more thicknesses. When the ink of the two continuous portions 70a and 70b is dry, the impregnated porous monolith 30 is placed on the ink of the two continuous portions 70a and 70b, with each of its ends extending over one of the two portions 70a and 70b such as to form a bridge between these portions.

In step b), illustrated by the device in section on the left and in plan view on the right, a second printing of 1,8-octanediol is carried out at the junction between the porous monolith 30 and the ink of the portions 70a and 70b to form vertical portions 72a and 72b respectively covering the ends of the porous monolith 30.

The porous monolith 30 is then held by the ink, by having its ends encapsulated in the ink respectively of the combination of the portions 70a and 72a and the portions 70b and 72b. It is raised relative to the initial support 20a by a height k of several micrometers to several millimeters. The height k may be substantially equal to the thickness of the ink of the portions 70a and 70b. It may be 200 μm.

In step c), illustrated by the device in section, a rectangular mold based on PDMS, which is open on the top and bottom faces and has dimensions less than or equal to those of the substrate, is placed on the substrate to enable the formation of the liquid polymer covering layer while preventing it from spreading. Liquid PDMS containing crosslinker is then added to the mold so as to cover entirely the course 62 formed by the ink and the porous monolith. The PDMS is subsequently crosslinked by heating, for example at 100° C. for 2 h or at ambient temperature for 24 h, or by heating at 40° C. for 2 h and then at 100° C. for 1 h. The PDMS passes under the porous monolith 30 between the portions 70a and 70b.

In step d), illustrated by the device in section, the initial support 20a is withdrawn and the ink of the course 62 of the assembly formed of the ink, the monolith and the crosslinked polymer is dissolved in the alcohol. The assembly is subsequently placed under vacuum and heated to 100° C. so that the residual ink present in the material is able to undergo sublimation and/or evaporation. To finish, the device is washed with a mixture of water/ethanol (50/50) and then with pure ethanol, before being dried in an oven at 40° C. for 24 h. This enables the formation of the microchannels 56a and 56b of the fluidic circuit 50 in the crosslinked polymer 25.

In step e), illustrated by the device in section, the assembly formed of the monolith, the crosslinked polymer and the channels 56a and 56b is fastened on a new support 20b, identical to or different from the initial support 20a, so as to close the channels 56a and 56b imperviously. Using a 0.5 mm punch for PDMS, cylindrical holes through the PDMS shell are formed on each end of the microchannels 56a and 56b to form the entry 40 and the exit 42.

The resulting device is used to carry out a chromatography, in particular an adsorption chromatography. In that case, the porous monolith, as stationary phase, enables the separation of molecules from a mixture such as the food dyes E133 and E129 by means of a gradient of water/acetonitrile mixture as mobile phase. Two dyes, E133 (blue) and E129 (red), are mixed. 200 μl of the mixture are inserted into the fluidic circuit via the entry 40 with a flow rate of 100 μl/min. The device is observed by the top with a camera. The entry channel 56a shows the color of the mixture when the mixture passes through it, and the monolith 30 shows a dark brown color which turns toward blue at the end of flow. The exit channel 56b shows a red color which is characteristic solely of the E129.

100 μl of water are then inserted into the fluidic circuit via the entry 40 with a flow rate of 100 μl/min. The entry channel 56a shows the color of the water when the water passes through it, and the monolith 30 shows an increasingly blue color, the E129 passing toward the exit channel 56b. Only the E133 is retained in the monolith; the E129 is then completely eluted.

400 μl of acetonitrile are then inserted into the fluidic circuit via the entry 40 with a flow rate of 100 μl/min. The E133 is then eluted, driving its migration along the monolith toward the exit 56b. The monolith is ultimately white, indicating complete elution of the E133.

It is therefore possible to carry out a chromatography with a device of this kind. As a variant, the portions 70a and 70b of the course 62 for forming the microchannels 56a and 56b may be formed via the use of a hollow element comprising an opening on its side wall at the junction position with the monolith. The junction between the hollow element and the monolith may then be made by printing at the junction. In this case, the method for extracting the ink may be similar to that described in relation to Example 2.

1. A method for manufacturing a device for the flow of a fluid on at least one fluid flow path passing through a porous or hollow solid element and at least a part of a fluidic circuit, the solid element and the part of the fluidic circuit being fluidically connected to one another, the method comprising the following steps:
a) printing a support with the course of the fluidic circuit with an ink and disposing the solid element on the support, the ink being contiguous with the solid element on the fluid flow path;
b) covering the solidified ink and the solid element with a crosslinkable polymer, the polymer being immiscible with the solidified ink;
c) crosslinking the polymer to solidify it; then
d) extracting the solidified ink to form the fluid flow path.

2. The method as claimed in claim 1, comprising a step of protecting at least a part of the pores or of the hollow or hollows of the solid element along the fluid flow path by filling at least a part of the solid element beforehand with a protective agent, which prevents penetration of the polymer into the solid element in the covering step b), and a step of extracting the protective agent after the polymer crosslinking step c) to enable fluid flow in the solid element.

3. The method as claimed in claim 1, wherein the solid element is porous, the polymer being crosslinked before the polymer has been able to fill the pores of at least one flow cross section of the fluid flow path of the solid element.

4. The method as claimed in claim 1, configured such that the polymer, outside the surface zone of the solid element in contact with the ink, penetrates the pores of the solid element between the covering step b) and the crosslinking step c) over a skin thickness of the solid element of less than or equal to 40% of the smallest dimension of the solid element in each flow cross section of the fluid flow path in the solid element.

5. The method as claimed in claim 1, wherein the support comprises a substrate made of a hydrophobic material.

6. The method as claimed in claim 1, wherein the support comprises a cavity for receiving the solid element on the surface, the solid element being disposed in the cavity in step a).

7. The method as claimed in claim 1, wherein the solid element is contiguous with a microchannel on the fluid flow pathway.

8. The method as claimed in claim 1, wherein the solid element extends on the fluid flow path such that the fluid flow path crosses the solid element from an entry point to an exit point, the entry and exit points being spaced apart by a distance of greater than or equal to 10% of the largest dimension of the solid element.

9. The method as claimed in claim 1, wherein the solid element is hollow, the open ends at the two ends of the hollow of the solid element being in the fluid flow path and the central axis of the hollow extending along the fluid flow path, the fluid flow path being maintained in the hollow by plugging of the two ends by a protective agent before the addition on the support or by the ink of the fluidic circuit attached to the hollow end of the solid element during step a).

10. The method as claimed in claim 1, wherein the solid element comprises a porous monolith having hierarchical porosity, or comprises a porous monolith and a protective outer sheath for the porous monolith that is open at the entry point and at the exit point of the fluid flow path, the ink being contiguous with at least one open end of the tube or the capillary in step a) of the method.

11. The method as claimed in claim 1, wherein the step of printing the course and disposing the solid element may comprise a first printing of ink and the disposing of the solid element on the support, then a second printing of ink to form the junction between the solid element and the ink of the first printing.

12. The method as claimed in claim 1, wherein the method comprises printing at least two respectively continuous portions separate from one another to form the course of the fluidic circuit, and disposing the solid element straddling the two portions.

13. The method as claimed in claim 1, comprising the formation of the porous monolith by a manufacturing method comprising:
the formation of a sol (5) comprising a sol-gel precursor in aqueous solution and,
the at least partial filling of an enclosure and of at least one mold contained in the enclosure with sol (5) formed beforehand, the mold comprising at least one opening opening into the sol (5) after filling with sol,
the formation of a sol-gel matrix in the enclosure from the sol (5),
the extraction of the mold with the sol-gel matrix contained in the mold from the enclosure, and
the formation of a porous monolith from the sol-gel matrix, where the sol, the sol-gel matrix and the porous monolith are formed by a sol-gel method.

14. The method as claimed in claim 1, wherein the ink and/or the protective agent are selected from the following:
linear glycols having the generic molecular formula C₂ₙH₄ₙ⁺²O₂ in which n is a positive integer greater than or equal to 1, preferably such that n=3, 4 or 5;
cyclohexanediol;
biphenyl;
tri(cyclohexyl)methane;
alcohols of molecular formula CₙH₂ₙ⁺²O in which n is a positive integer greater than or equal to 1, preferably such that n=10, 11 or 12;
and mixtures thereof.

15. The method as claimed in claim 1, comprising the withdrawal of at least a part of the support.

16. The method as claimed in claim 5, wherein the support comprises one or more support elements (28; 28a, 28b) placed on the substrate, the support comprising at least two support elements on the substrate, which are spaced apart by a nonzero distance, the device being configured such that the solid element is disposed in step a) straddling the two support elements.
